(19) United States
(12) Patent Application Publication
(10) Pub. No.: US 2011/0204374 A1
(43) Pub. Date: Aug. 25, 2011

(54) THIN FILM DIODE AND METHOD FOR FABRICATING THE SAME

(75) Inventor: Tomohiro Kimura, Osaka-shi (JP)

(73) Assignee: SHARP KABUSHIKI KAISHA, Osaka-shi, Osaka (JP)

(21) Appl. No.: 13/126,562

(22) PCT Filed: Aug. 26, 2009
(86) PCT No.: PCT/JP2009/004123

§ 371 Date: Apr. 28, 2011

(30) Foreign Application Priority Data
Jan. 20, 2009 (JP) 2009-010164

(51) Int. Cl. H01L 27/12; H01L 21/329

(52) U.S. Cl. 257/66; 438/479; 257/E27.111; 257/E21.352

(57) ABSTRACT

A TFD (21) includes: a glass substrate (10); a polysilicon layer (12a) formed on the glass substrate (10), and including a p-type semiconductor region (12ap) and an n-type semiconductor region (12an) which are both formed in a same plane and doped with impurity ions; and an insulating film (13) provided to cover the polysilicon layer (12a). In at least one of the p-type semiconductor region (12ap) or the n-type semiconductor region (12an), the concentration of the impurity ions in a multilayer of the polysilicon layer (12a) and the insulating film (13) along the thickness of the multilayer reaches a peak concentration in the insulating film (13) or in a portion of the polysilicon layer (12a) located between the midpoint of the thickness of the polysilicon layer (12a) and the insulating film (13).

### TECHNICAL FIELD

The present invention relates to thin film diodes and methods for fabricating the same, and more particularly relates to a thin film diode formed on a glass substrate, and a method for fabricating the same.

### BACKGROUND ART

A thin film diode (hereinafter referred to as the “TFD”) includes, e.g., a polysilicon layer including a p-type semiconductor region doped with boron ions and an n-type semiconductor region doped with phosphorus ions.

For example, PATENT DOCUMENT 1 describes a semiconductor device in which the leakage current flowing through a backward diode is increased by steepening the concentration gradient at the pn junction interface of a diode made of polysilicon or by amorphizing the vicinity of the junction interface.

TFDs function as optical sensor devices for converting optical signals into electrical signals, and thus, in recent years, a display has been suggested in which a TFD is mounted, as an optical sensor device, on a thin film transistor (hereinafter referred to as “TFT”) substrate including a TFT as a switching device.

For example, PATENT DOCUMENT 2 describes a method for fabricating an array substrate. In this method, an active layer of a thin film transistor formed on a glass substrate and a photoelectric converter of a pin diode formed thereon are made of an amorphous silicon thin film, and the active layer and the photoelectric converter are doped with impurities as necessary in the same process step to have different doping concentrations. PATENT DOCUMENT 2 further describes that according to this method, a thin film transistor having desired characteristics and a pin diode of which the photosensitivity is improved can be easily fabricated on a glass substrate at the same time by a small number of process steps.

### Citation List

### Patent Document

PATENT DOCUMENT 1: International Patent Publication No. W096/33514

PATENT DOCUMENT 2: Japanese Patent Publication No. 2005-43672

### SUMMARY OF THE INVENTION

### Technical Problem

FIG. 13 is a cross-sectional view schematically illustrating a conventional TFD 121.

As illustrated in FIG. 13, the TFD 121 includes a polysilicon layer 112 formed on a glass substrate 110 with a base coating film 111 interposed therebetween, and an insulating film 113 covering the polysilicon layer 112.

As illustrated in FIG. 13, the polysilicon layer 112 includes a p-type semiconductor region 112p heavily doped with boron ions serving as impurities, an n-type semiconductor region 112n heavily doped with phosphorus ions serving as impurities, and an i-type semiconductor region 112i which is not doped with impurities, and forms a portion of a diode with a PIN (positive-intrinsic-negative) structure.

Here, in fabricating the conventional TFD 121, after the doping of ions as impurities, the substrate needs to be heated to recover the crystallinity, which has been destroyed by the doping of the impurity ions, of the polysilicon layer 112 and activate the impurity ions with which the polysilicon layer 112 has been doped. However, it is difficult to heat the TFD 121 using the glass substrate 110 at high temperatures, and thus, the crystallinity of the polysilicon layer 112 tends to be insufficiently recovered. Therefore, in the polysilicon layer 112, the crystallinity of a junction between the p-type semiconductor region 112p and the i-type semiconductor region 112i and the crystallinity of a junction between the n-type semiconductor region 112n and the i-type semiconductor region 112i are reduced, thereby degrading the characteristics of the diode.

The present invention has been made in view of the foregoing point, and it is an object of the present invention to increase the crystallinity of a junction as much as possible to improve the diode characteristics.

### Solution to the Problem

In order to achieve the above object, the present invention is configured such that the concentration of impurity ions in a multilayer of a polysilicon layer and an insulating film along the thickness of the multilayer reaches a peak concentration in the insulating film or in a portion of the polysilicon layer located between the midpoint of the thickness of the polysilicon layer and the insulating film.

Specifically, a thin film diode according to the present invention includes: a glass substrate; a polysilicon layer formed on the glass substrate, and including a p-type semiconductor region and an n-type semiconductor region which are both formed in a same plane and doped with impurity ions; and an insulating film provided to cover the polysilicon layer. In at least one of the p-type semiconductor region or the n-type semiconductor region, a concentration of the impurity ions in a multilayer of the polysilicon layer and the insulating film along a thickness of the multilayer reaches a peak concentration in the insulating film or in a portion of the polysilicon layer located between a midpoint of a thickness of the polysilicon layer and the insulating film.

With the above configuration, the concentration of the impurity ions in the multilayer of the polysilicon layer and the insulating film along the thickness of the multilayer reaches a peak concentration in the insulating film or in the portion of the polysilicon layer located between the midpoint of the thickness of the polysilicon layer and the insulating film. Therefore, in at least one of the p-type semiconductor region or the n-type semiconductor region, the concentration of the impurity ions in the polysilicon layer along the thickness of the polysilicon layer is lowest in the surface of the polysilicon layer located near the glass substrate, thereby reducing the destruction of the crystallinity of a part of the polysilicon layer located near the glass substrate.

Here, FIG. 9(a) is an optical micrograph of a region Aa into which impurity ions are implanted and its surrounding region before heating, and FIG. 9(b) illustrates Raman spectra of an X portion and a Y portion in FIG. 9(a). As illustrated in FIG. 9(b), since the spectrum of the Y portion of a non-implanted region has a sharp peak attributed to polysilicon in the vicinity of a wave number of 520 cm⁻¹, the Y portion presumably has excellent crystallinity, and since the spectrum profile of the X portion at the center of the implanted region Aa substantially coincides with the spectrum profile of amorphous silicon, the crystallinity of polysilicon in the X portion is presumably destroyed by the implantation of the impurity ions.

FIG. 10(a) is an optical micrograph of the region Aa into which impurity ions are implanted and its surrounding region after heating, and FIG. 10(b) illustrates Raman spectra of an Xa portion, an Xb portion, and an Xc portion in FIG. 10(a). Since, as illustrated in FIG. 10(b), the spectrum of the Xc portion of an end portion of the implanted region Aa has a sharp peak attributed to polysilicon in the vicinity of a wave number of 520 cm⁻¹, the crystallinity of the Xc portion is presumably recovered.

In the experiments in FIGS. 9 and 10, the region Aa of the polysilicon layer was doped with impurity ions with a relatively low acceleration voltage (of, e.g., 20 keV) so that the concentration of the impurity ions along the thickness of the polysilicon layer reaches a peak concentration in a part of the polysilicon layer located near the insulating film. By contrast, in the below-described experiments in FIGS. 11 and 12, a region Ab of the polysilicon layer was doped with impurity ions with a relatively high acceleration voltage (of, e.g., 35 keV) so that the concentration of the impurity ions along the thickness of the polysilicon layer reaches a peak concentration in a part of the polysilicon layer located near the glass substrate. Specifically, FIG. 11(a) is an optical micrograph of the region Ab into which impurity ions are implanted and its surrounding region before heating, and FIG. 11(b) illustrates Raman spectra of an X portion and a Y portion in FIG. 11(a). FIG. 12(a) is an optical micrograph of the region Ab into which impurity ions are implanted and its surrounding region after heating, and FIG. 12(b) illustrates a Raman spectrum of an Xc portion in FIG. 12(a). Since, as illustrated in FIG. 12(b), the spectrum profile of the Xc portion of an end portion of the implanted region Ab is close to that of amorphous silicon, the crystallinity of the Xc portion is presumably incompletely recovered by the heating.

The above description shows the finding that while the crystallinity of a portion, which is in contact with a non-implanted region, of the region Aa into which impurity ions are implanted is quickly recovered, the crystallinity of a central portion thereof which is apart from the non-implanted region is slowly recovered, and thus, when the crystallinity of a region from which recovery of the crystallinity starts is high, this accelerates the recovery of the crystallinity.

When the finding associated with the recovery of the crystallinity of the polysilicon layer along the surface thereof is represented to correspond to the recovery of the crystallinity along the thickness, the recovery of the crystallinity starts from a part of the polysilicon layer located near the glass substrate, thereby accelerating the recovery of the crystallinity. The reason for this is that as described above, the destruction of the crystallinity of a part, which is located near the glass substrate, of at least one of the p-type semiconductor region or the n-type semiconductor region of the polysilicon layer is reduced. As such, the crystallinity of at least one of the p-type semiconductor region or the n-type semiconductor region of the polysilicon layer is increased as much as possible, thereby increasing the crystallinities of junctions of the polysilicon layer as much as possible. Therefore, the crystallinities of the junctions are increased as much as possible, thereby improving the diode characteristics.

In at least one of the p-type semiconductor region or the n-type semiconductor region, the concentration of the impurity ions in a surface of the polysilicon layer located near the glass substrate may be less than or equal to 1/10 of a peak of the concentration of the impurity ions in the multilayer of the polysilicon layer and the insulating film along the thickness.

With the above configuration, in at least one of the p-type semiconductor region or the n-type semiconductor region, the concentration of the impurity ions in the surface of the polysilicon layer located near the glass substrate may be less than or equal to 1/10 of the peak of the concentration of the impurity ions in the multilayer of the polysilicon layer and the insulating film along the thickness. Therefore, the concentration of the impurity ions in the polysilicon layer along the thickness of the polysilicon layer is specifically lowest in the surface of the polysilicon layer located near the glass substrate.

An i-type semiconductor region which is not doped with impurity ions may be provided between the p-type semiconductor region and the n-type semiconductor region.

With the above configuration, the i-type semiconductor region is provided between the p-type semiconductor region and the n-type semiconductor region. Therefore, a diode with a PIN structure is specifically configured, thereby obtaining an optical sensor device exhibiting excellent responsivity.

The thin film diode may further include: a further polysilicon film formed in a layer in which the polysilicon layer is formed. The further polysilicon layer may form a portion of a thin film transistor.

With the above configuration, the further polysilicon layer forms a portion of a thin film transistor. Therefore, the thin film transistor can be utilized as a driver for reading the current value of the thin film diode functioning as an optical sensor device, and a display, an image sensor, etc., can be obtained which each include a thin film diode mounted, as an optical sensor device, on a thin film transistor substrate including a thin film transistor as a switching device and have a touch sensing capability.

A method for fabricating a thin film diode according to the present invention includes: a polysilicon layer formation step of forming a polysilicon layer on a glass substrate; an insulating film formation step of forming an insulating film to cover the polysilicon layer; a p-type semiconductor region formation step of doping the polysilicon layer with impurity ions via the insulating film, thereby forming a p-type semiconductor region; an n-type semiconductor region formation step of doping the polysilicon layer with impurity ions via the insulating film, thereby forming an n-type semiconductor region; a heating step of heating the glass substrate over which the p-type semiconductor region and the n-type semiconductor region are formed, thereby recovering a crystallinity of the polysilicon layer and activating the impurity ions with which the polysilicon layer is doped. In at least one of the p-type semiconductor region formation step or the n-type semiconductor region formation step, the polysilicon layer is doped with the impurity ions such that a concentration of the impurity ions in a multilayer of the polysilicon layer and the insulating film along a thickness of the multilayer reaches a peak concentration in the insulating film or in a portion of the polysilicon layer located between a midpoint of a thickness of the polysilicon layer and the insulating film.

According to the above method, in at least one of the p-type semiconductor region formation step or the n-type semiconductor region formation step, the polysilicon layer is doped with the impurity ions so that the concentration of the impurity ions in the multilayer of the polysilicon layer and the insulating film along the thickness of the multilayer reaches a peak concentration in the insulating film or in a portion of the polysilicon layer located between the midpoint of the thickness of the polysilicon layer and the insulating film. Therefore, in at least one of the p-type semiconductor region or the n-type semiconductor region, the concentration of the impurity ions in the polysilicon layer along the thickness of the polysilicon layer is lowest in the surface of the polysilicon layer located near the glass substrate, thereby reducing the destruction of the crystallinity of a part of the polysilicon layer located near the glass substrate.

Here, FIG. 9(a) is an optical micrograph of the region Aa into which impurity ions are implanted and its surrounding region before heating, and FIG. 9(b) illustrates Raman spectra of the X portion and the Y portion in FIG. 9(a). As illustrated in FIG. 9(b), since the spectrum of the Y portion of a non-implanted region has a sharp peak attributed to polysilicon in the vicinity of a wave number of 520 cm⁻¹, the Y portion presumably has excellent crystallinity, and since the spectrum profile of the X portion at the center of the implanted region Aa substantially coincides with the spectrum profile of amorphous silicon, the crystallinity of polysilicon in the X portion is presumably destroyed by the implantation of the impurity ions.

FIG. 10(a) is an optical micrograph of the region Aa into which impurity ions are implanted and its surrounding region after heating, and FIG. 10(b) illustrates Raman spectra of the Xa portion, the Xb portion, and the Xc portion in FIG. 10(a). Since, as illustrated in FIG. 10(b), the spectrum of the Xc portion of an end portion of the implanted region Aa has a sharp peak attributed to polysilicon in the vicinity of a wave number of 520 cm⁻¹, the crystallinity of the Xc portion is presumably recovered.

In the experiments in FIGS. 9 and 10, the region Aa of the polysilicon layer was doped with impurity ions with a relatively low acceleration voltage (of, e.g., 20 keV) so that the concentration of the impurity ions along the thickness of the polysilicon layer reaches a peak concentration in a part of the polysilicon layer located near the insulating film. By contrast, in the below-described experiments in FIGS. 11 and 12, the region Ab of the polysilicon layer was doped with impurity ions with a relatively high acceleration voltage (of, e.g., 35 keV) so that the concentration of the impurity ions along the thickness of the polysilicon layer reaches a peak concentration in a part of the polysilicon layer located near the glass substrate. Specifically, FIG. 11(a) is an optical micrograph of the region Ab into which impurity ions are implanted and its surrounding region before heating, and FIG. 11(b) illustrates Raman spectra of the X portion and the Y portion in FIG. 11(a). FIG. 12(a) is an optical micrograph of the region Ab into which impurity ions are implanted and its surrounding region after heating, and FIG. 12(b) illustrates a Raman spectrum of the Xc portion in FIG. 12(a). Since, as illustrated in FIG. 12(b), the spectrum profile of the Xc portion of an end portion of the implanted region Ab is close to that of amorphous silicon, the crystallinity of the Xc portion is presumably incompletely recovered by the heating.

The above description shows the finding that while the crystallinity of a portion, which is in contact with a non-implanted region, of the region Aa into which impurity ions are implanted is quickly recovered, the crystallinity of a central portion thereof which is apart from the non-implanted region is slowly recovered, and thus, when the crystallinity of a region from which recovery of the crystallinity starts is high, this accelerates the recovery of the crystallinity.

When the finding associated with the recovery of the crystallinity of the polysilicon layer along the surface thereof is represented to correspond to the recovery of the crystallinity along the thickness, the recovery of the crystallinity starts from a part of the polysilicon layer located near the glass substrate in the heating step, thereby accelerating the recovery of the crystallinity. The reason for this is that as described above, the destruction of the crystallinity of a part, which is located near the glass substrate, of at least one of the p-type semiconductor region or the n-type semiconductor region of the polysilicon layer is reduced. As such, the crystallinity of at least one of the p-type semiconductor region or the n-type semiconductor region of the polysilicon layer is increased as much as possible, thereby increasing the crystallinities of junctions of the polysilicon layer as much as impossible. Therefore, the crystallinities of the junctions are increased as much as possible, thereby improving the diode characteristics.

In at least one of the p-type semiconductor region formation step or the n-type semiconductor region formation step, an acceleration voltage in the doping of the impurity ions may be set low such that the concentration of the impurity ions in the multilayer of the polysilicon layer and the insulating film along the thickness of the multilayer reaches a peak concentration in the insulating film or in the portion of the polysilicon layer located between the midpoint of the thickness of the polysilicon layer and the insulating film.

According to the above method, when the acceleration voltage in the doping of the impurity ions is set low, the impurity ions are less likely to reach the surface of the polysilicon layer located near the glass substrate. Therefore, in at least one of the p-type semiconductor region or the n-type semiconductor region, the concentration of the impurity ions in the polysilicon layer along the thickness of the polysilicon layer is specifically lowest in the surface of the polysilicon layer located near the glass substrate.

In the insulating film formation step, the insulating film may be formed thick enough to allow the concentration of the impurity ions in a multilayer of the insulating film and at least one of a region of the polysilicon layer which will form the p-type semiconductor region or a region of the polysilicon layer which will form the n-type semiconductor region along the thickness of the multilayer to reach a peak concentration in the insulating film or in the portion of the polysilicon layer located between the midpoint of the thickness of the polysilicon layer and the insulating film.

According to the above method, when the insulating film covering the polysilicon layer is formed thick enough, the distance from the top surface of the insulating film to the surface of the polysilicon layer located near the glass substrate is increased, and thus, the impurity ions are less likely to reach the surface of the polysilicon layer located near the glass substrate. Therefore, in at least one of the p-type semiconductor region or the n-type semiconductor region, the concentration of the impurity ions in the polysilicon layer along the thickness of the polysilicon layer is specifically lowest in the surface of the polysilicon layer located near the glass substrate.

In the polysilicon layer formation step, the polysilicon layer may be formed thick enough to allow the concentration of the impurity ions in a multilayer of the insulating film and at least one of a region of the polysilicon layer which will form the p-type semiconductor region or a region of the polysilicon layer which will form the n-type semiconductor region along the thickness of the multilayer to reach a peak concentration in the insulating film or in the portion of the polysilicon layer located between the midpoint of the thickness of the polysilicon layer and the insulating film.

According to the above method, when the insulating film itself is formed thick enough, the distance from the top surface of the insulating film to the surface of the polysilicon layer located near the glass substrate is increased, and thus, the impurity ions are less likely to reach the surface of the polysilicon layer located near the glass substrate. Therefore, in at least one of the p-type semiconductor region or the n-type semiconductor region, the concentration of the impurity ions in the polysilicon layer along the thickness of the polysilicon layer is specifically lowest in the surface of the polysilicon layer located near the glass substrate.

### ADVANTAGES OF THE INVENTION

According to the present invention, in at least one of the p-type semiconductor region or the n-type semiconductor region, the concentration of the impurity ions in the multilayer of the polysilicon layer and the insulating film along the thickness of the multilayer reaches a peak concentration in the insulating film or in the portion of the polysilicon layer located between the midpoint of the thickness of the polysilicon layer and the insulating film. Therefore, the crystallinities of the junctions are increased as much as possible, thereby improving the diode characteristics.

### BRIEF DESCRIPTION OF THE DRAWINGS

FIG. 1 is a plan view schematically illustrating a liquid crystal display 50 according to an embodiment of the present invention.

FIG. 2 is a cross-sectional view of a TFD 21 and a TFT 22 which form portions of the liquid crystal display 50.

FIG. 3 is a cross-sectional view schematically illustrating an ion implantation profile C of the TFD 21.

FIG. 4 illustrates cross-sectional views schematically illustrating other ion implantation profiles C of the TFD 21.

FIG. 5 illustrates cross-sectional views illustrating process steps for forming the TFD 21 and the TFT 22 which form portions of the liquid crystal display 50.

FIG. 6 is a cross-sectional view schematically illustrating the direction in which the crystallinity of the TFD 21 is recovered.

FIG. 7 is a graph illustrating the relationship between the dark current and anode-to-cathode voltage of a TFD.

FIG. 8 is a graph illustrating the relationship between the light-to-dark current ratio and anode-to-cathode voltage of the TFD.

FIG. 9(a) is an optical micrograph of a region Aa into which impurity ions are implanted and its surrounding region before heating, and FIG. 9(b) illustrates Raman spectra thereof.

FIG. 10(a) is an optical micrograph of the region Aa into which impurity ions are implanted and its surrounding region after heating, and FIG. 10(b) illustrates Raman spectra thereof.

FIG. 11(a) is an optical micrograph of a region Ab into which impurity ions are implanted and its surrounding region before heating, and FIG. 11(b) illustrates Raman spectra thereof.

FIG. 12(a) is an optical micrograph of the region Ab into which impurity ions are implanted and its surrounding region after heating, and FIG. 12(b) illustrates a Raman spectrum thereof.

FIG. 13 is a cross-sectional view schematically illustrating a conventional TFD 121.

### DESCRIPTION OF EMBODIMENT

An embodiment of the present invention will be described hereinafter in detail with reference to the drawings. The present invention is not limited to the following embodiment.

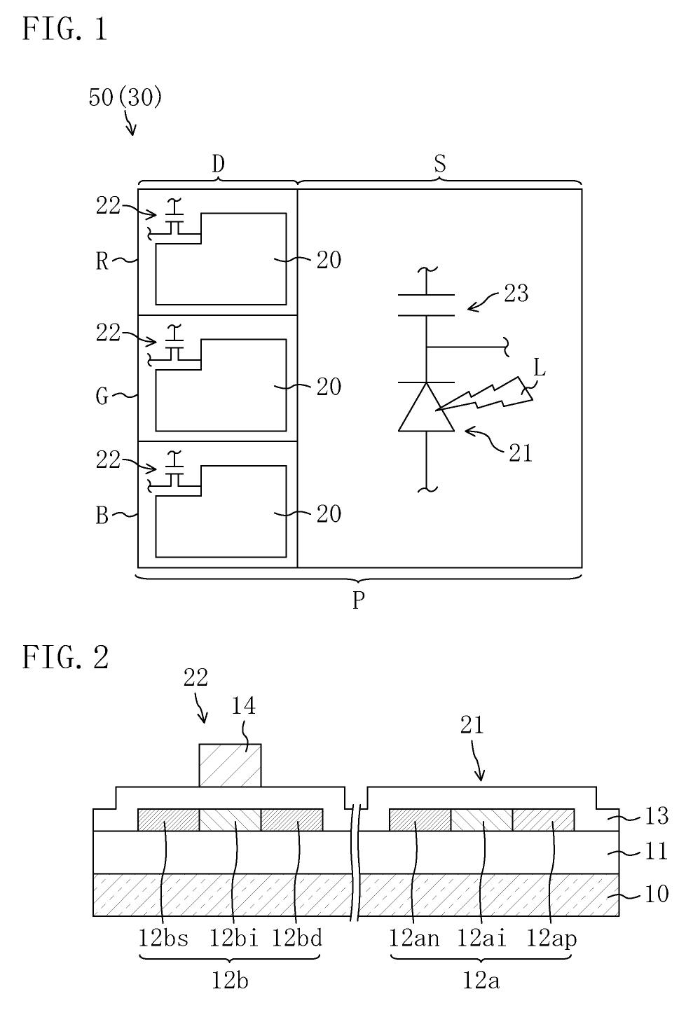

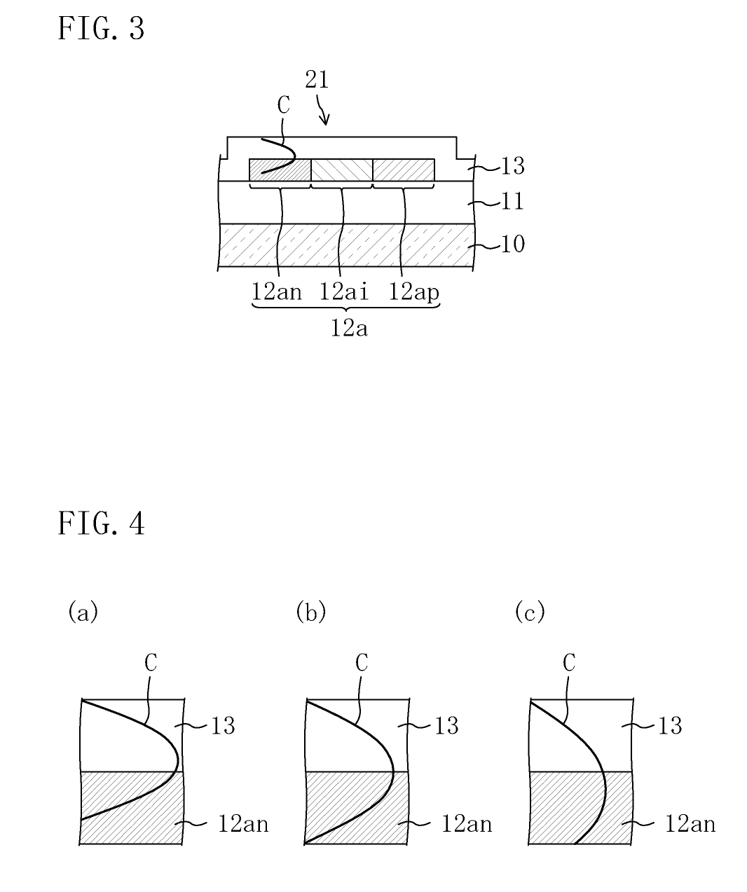

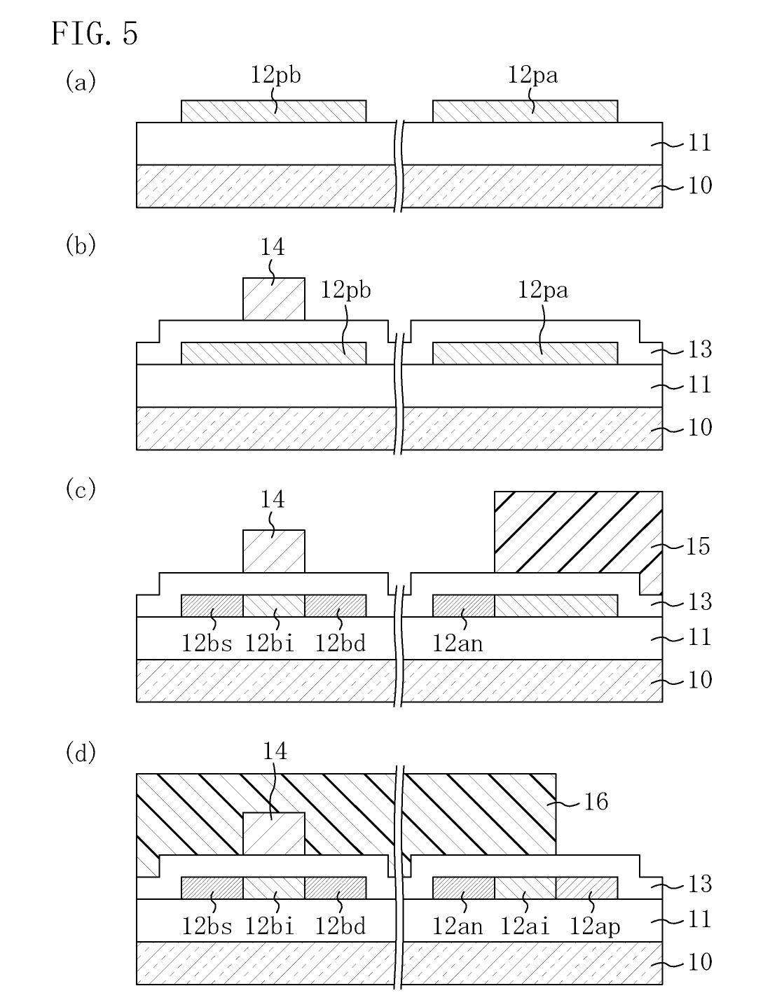

FIG. 1 is a plan view schematically illustrating a liquid crystal display 50 of this embodiment, and FIG. 2 is a cross-sectional view of a TFD 21 and a TFT 22 which form portions of the liquid crystal display 50. FIG. 3 is a cross-sectional view schematically illustrating an ion implantation profile C of the TFD 21, and FIG. 4 illustrates cross-sectional views schematically illustrating other ion implantation profiles C of the TFD 21.

As illustrated in FIG. 1, the liquid crystal display 50 includes a TFT substrate 30, a CF substrate (not shown) facing the TFT substrate 30, a liquid crystal layer (not shown) provided between the TFT substrate 30 and the CF substrate, and a frame-like sealant (not shown) with which the TFT substrate 30 and the CF substrate are bonded together and which encloses the liquid crystal layer between the TFT substrate and the CF substrate.

A plurality of pixels P (see FIG. 1) are arranged in a matrix on the TFT substrate 30.

As illustrated in FIG. 1, the pixels P each include a display region D in which a pixel region R configured to display a red color, a pixel region G configured to display a green color, and a pixel region B configured to display a blue color are aligned vertically and which is configured to display an image, and a sensor region S which is located adjacent to the display region D to detect the touched location.

As illustrated in FIG. 1, the pixel regions R, G, and B each include a pixel electrode 20, and a TFT 22 connected to the pixel electrode 20. Here, gate lines (not shown) and source lines (not shown) surround the pixel electrode 20, and while the gate lines extend along the upper (or lower) edges of the pixel electrodes 20 in FIG. 1, the source lines (not shown) extend along the left (or right) edges of the pixel electrodes 20 in FIG. 1.

As illustrated in FIG. 2, the TFT 22 includes a polysilicon layer 12b formed on a glass substrate 10 with a base coating film 11 interposed therebetween, a portion of a gate insulating film 13 covering the polysilicon layer 12b, and a gate electrode 14 formed on the gate insulating film 13 and connected to the corresponding gate line.

As illustrated in FIG. 2, the polysilicon layer 12b includes a source region 12bs connected to the corresponding source line, a drain region 12bd connected to the corresponding pixel electrode 20, and a channel region 12bi formed between the source region 12bs and the drain region 12bd to overlap the gate electrode 14.

As illustrated in FIG. 1, each of sensor regions S includes a TFD 21 provided as an optical sensor device, and a capacitor 23 connected to the TFD 21. When, in the sensor region S, the capacitor 23 is charged by applying a voltage in the forward direction of the TFD 21 for a predetermined time, and light L is incident on the TFD 21, current leaks from the capacitor 23, thereby reducing the potential of the capacitor 23. Thus, the incidence of the light L is detected by measuring the voltage of the capacitor 23 after the predetermined time.

As illustrated in FIG. 2, the TFD 21 includes a polysilicon layer 12a formed on the glass substrate 10 with the base coating film 11 interposed therebetween, and a portion of the gate insulating film 13 covering the polysilicon layer 12a.

As illustrated in FIG. 2, the polysilicon layer 12a includes, e.g., a p-type semiconductor region 12ap which is an anode heavily doped with boron ions serving as impurities, an n-type semiconductor region 12an which is a cathode heavily doped with phosphorus ions serving as impurities, and an i-type semiconductor region 12ai which is formed between the p-type semiconductor region 12ap and the n-type semiconductor region 12an and which is not doped with impurities, and the polysilicon layer 12a forms a portion of the diode with a PIN structure.

As illustrated in FIG. 3, in the n-type semiconductor region 12an, the concentration of the impurity ions in a multilayer of the polysilicon layer 12a and the gate insulating film 13 along the thickness of the multilayer (see the ion implantation profile C in FIG. 3) reaches a peak concentration in the insulating film 13 or in a portion of the polysilicon layer 12a located between the midpoint of the thickness of the polysilicon layer 12a and the insulating film 13. Here, the peak of the concentration of the impurity ions in the multilayer of the polysilicon layer 12a and the gate insulating film 13 along the thickness of the multilayer may be present in the gate insulating film 13 as illustrated in FIG. 4(a), may be present at the interface between the n-type semiconductor region 12an (the polysilicon layer 12a) and the gate insulating film 13 as illustrated in FIG. 4(b), or may be present in an upper half portion of the n-type semiconductor region 12an (the polysilicon layer 12a) as illustrated in FIG. 4(c). The concentration of the impurity ions in the surface, located near the glass substrate 10, of the n-type semiconductor region 12an of the polysilicon layer 12a is preferably less than or equal to 1/10 of the peak (e.g., 1×10⁺²⁰/cm³−1×10⁺²¹/cm³) of the concentration of the impurity ions in the multilayer of the polysilicon layer 12a and the gate insulating film 13 along the thickness of the multilayer.

The CF substrate includes a red layer (not shown) formed to overlap the pixel region R of the TFT substrate 30, a green layer (not shown) formed to overlap the pixel region G thereof, a blue layer (not shown) formed to overlap the pixel region B thereof, a transparent layer (not shown) formed to overlap the sensor region S thereof, a black matrix (not shown) provided between each adjacent pair of the red layer, the green layer, the blue layer, and the transparent layer, a common electrode (not shown) provided to cover the red layer, the green layer, the blue layer, the transparent layer, and the black matrix, and an alignment film (not shown) provided to cover the common electrode.

The liquid crystal layer is made of a nematic liquid crystal material, etc., having electro-optic characteristics.

The liquid crystal display 50 having the above configuration is configured so that: for example, the transmittance of light incident from a backlight is adjusted by applying a predetermined voltage to a region, which corresponds to each of the pixel regions R, G, and B, of the liquid crystal layer provided between the TFT substrate 30 and the CF substrate, thereby displaying an image; and when a display screen is touched, the amount of light received by the TFD 21 provided in the sensor region S is changed, thereby detecting the touched location based on the voltage of the capacitor 23 at the time of the touch.

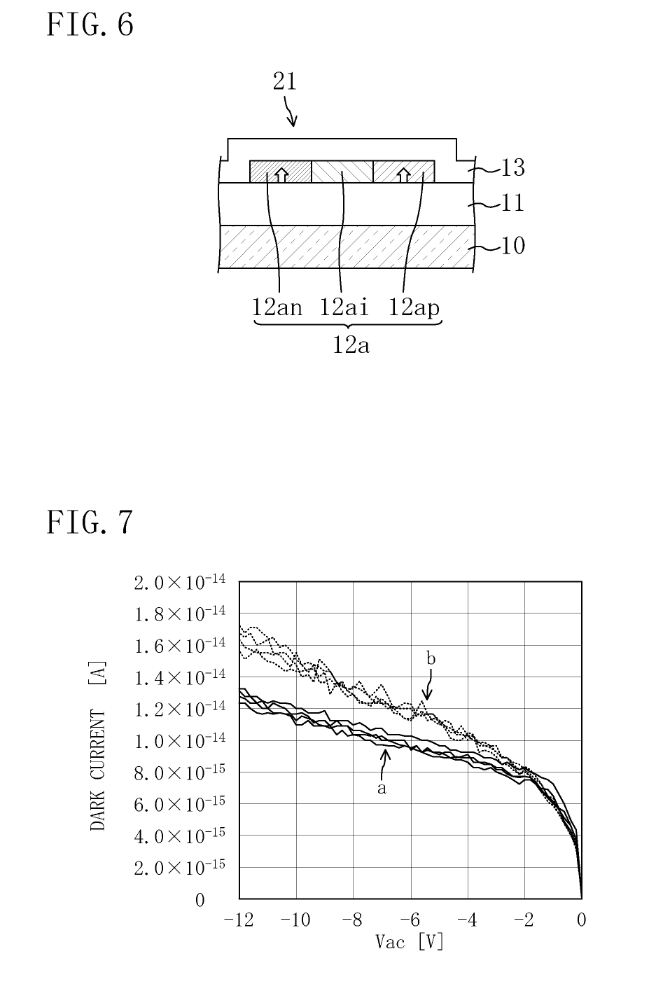

Next, a method for fabricating the TM 21 and the TFT 22 which form portions of the liquid crystal display 50 of this embodiment will be described with reference to FIGS. 5 and 6. Here, FIG. 5 illustrates cross-sectional views illustrating process steps of forming the TFD 21 and the TFT 22 which form portions of the liquid crystal display 50, and FIG. 6 is a cross-sectional view schematically illustrating the direction in which the crystallinity of the TFD 21 is recovered. The fabrication method of this embodiment includes a polysilicon layer formation process step, a gate insulating film formation process step, a gate electrode formation process step, an n-type semiconductor region formation process step, a p-type semiconductor region formation process step, and a heating process step.

<Polysilicon Layer Formation Process Step>

First, e.g., a silicon oxide film is deposited on an entire glass substrate 10 by plasma chemical vapor deposition (CVD), thereby forming a base coating film 11.

Subsequently, an amorphous silicon film (having, e.g., a thickness of about 50 nm) is deposited, by plasma CVD using disilane, etc., as a material gas, on the entire substrate on which the base coating film 11 is formed, and then is heated by the irradiation of laser light, etc., so as to be converted into a polysilicon film. Thereafter, the polysilicon film is patterned by photolithography, thereby forming polysilicon layers 12pa and 12pb as illustrated in FIG. 5(a).

<Gate Insulating Film Formation Process Step>

A silicon oxide film (having, e.g., a thickness of about 30 nm) is deposited, by plasma CVD, on the entire substrate over which the polysilicon layers 12pa and 12pb are formed in the polysilicon layer formation process step, thereby forming a gate insulating film 13.

<Gate Electrode Formation Process Step>

A tantalum nitride film and a tungsten film are sequentially deposited, by sputtering, on the entire substrate over which the gate insulating film 13 is formed in the gate insulating film formation process step, and then are patterned by photolithography, thereby forming a gate electrode 14 as illustrated in FIG. 5(b).

<N-type Semiconductor Region Formation Process Step>

First, the entire substrate over which the gate electrode 14 is formed in the gate electrode formation process step is coated with a photosensitive resin by spin coating, and then is partially exposed to light and developed, thereby forming a photoresist 15 (see FIG. 5(c)).

Subsequently, the polysilicon layers 12pa and 12pb are doped with, e.g., phosphorus ions serving as impurity ions via the gate insulating film 13 with a predetermined acceleration voltage (e.g., 20 keV) by using the gate electrode 14 and the photoresist 15 as masks (e.g., the average dose: 8×10⁺¹⁴/cm²). Thus, as illustrated in FIG. 5(c), a channel region 12bi is formed in a portion of the polysilicon layer 12pb overlapping the gate electrode 14; a source region 12bs and a drain region 12bd are formed in portions thereof located outside the channel region 12bi; and an n-type semiconductor region 12an is formed in a portion of the polysilicon layer 12pa exposed from the photoresist 15.

<P-type Semiconductor Region Formation Process Step>

First, the photoresist 15 is removed from the substrate over which the n-type semiconductor region 12an, etc., are formed in the n-type semiconductor region formation process step, and thereafter, the entire substrate region is coated with a photosensitive resin by spin coating, and then is partially exposed to light and developed, thereby forming a photoresist 16 (see FIG. 5(d)).

Subsequently, the polysilicon layer 12pa is doped with, e.g., boron ions serving as impurity ions via the gate insulating film 13 by using the photoresist 16 as a mask, thereby forming a p-type semiconductor region 12ap in a portion of the polysilicon layer 12pa exposed from the photoresist 16 as illustrated in FIG. 5(d).

<Heating Process Step>

The photoresist 16 is removed from the substrate over which the p-type semiconductor region 12ap is formed in the p-type semiconductor region formation process step, and then the substrate is heated at 550° C. for an hour, thereby recovering the crystallinities of the polysilicon layers 12a and 12b and activating the impurity ions with which the polysilicon layers 12pa and 12pb are doped in the n-type semiconductor region formation process step and the p-type semiconductor region formation process step. Here, as illustrated in FIG. 6, in the heating process step, the crystallinity of the polysilicon layer 12a is recovered from the surface of the polysilicon layer 12a located near the glass substrate 10 and doped with the impurity ions at a relatively low dose to reduce the destruction of the crystallinity (see the arrows in this figure).

In the above-described manner, the TFD 21 and the TFT 22 of this embodiment can be fabricated. Thereafter, an inorganic insulating film is formed to cover the TFD 21 and the TFT 22; contact holes are subsequently formed in the inorganic insulating film; source lines, etc., are then formed on the inorganic insulating film to fill the contact holes; an organic insulating film is formed to cover the source lines, etc.; contact holes are then formed in the organic insulating film; pixel electrodes 20 are subsequently formed on the organic insulating film to fill the contact holes; and an alignment film is formed to cover the pixel electrodes 20, thereby fabricating a TFT substrate 30.

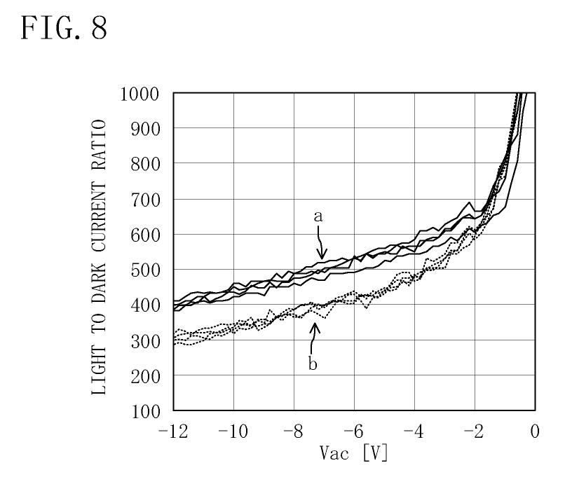

Next, specifically conducted experiments will be described with reference to FIGS. 7 and 8. Here, FIG. 7 is a graph illustrating the relationship between the dark current and anode-to-cathode voltage of a TFD. FIG. 8 is a graph illustrating the relationship between the light-to-dark current ratio and anode-to-cathode voltage of the TFD.

More specifically, a TFD was fabricated, as an example of the present invention, by the above-described fabrication method, and a TFD was fabricated, as a comparative example of the present invention, under conditions where the acceleration voltage in the doping of phosphorus ions in the above-described fabrication method was 35 keV (corresponding to the conventional condition), and where the average dose in this doping was 3×10⁺¹⁴/cm² in order to allow the sheet resistance of the TFD to be identical with that of the TFD of the example. Then, the characteristics of these diodes were evaluated.

Out of the diode characteristics, the relationship between the dark current (0 lx) and anode-to-cathode voltage of each of the TFDs was first evaluated.

As illustrated in FIG. 7, it was found that in the example (the solid lines a in this figure) in which the doping is performed with a relatively low acceleration voltage, the dark current is lower than that in the comparative example (the broken lines b in this figure) in which the doping is performed with a relatively high acceleration voltage.

Furthermore, the relationship between the light (10000 lx)-to-dark (0 lx) current ratio and anode-to-cathode voltage of each of the TFDs was evaluated.

As illustrated in FIG. 8, it was found that in the example (the solid lines a in this figure) in which the doping is performed with a relatively low acceleration voltage, the light-to-dark current ratio is greater than that in the comparative example (the broken lines b in this figure) in which the doping is performed with a relatively high acceleration voltage.

The above experiments showed that according to the present invention, the sensitivity (dynamic range) of the TFD, i.e., the characteristic of the diode, is improved.

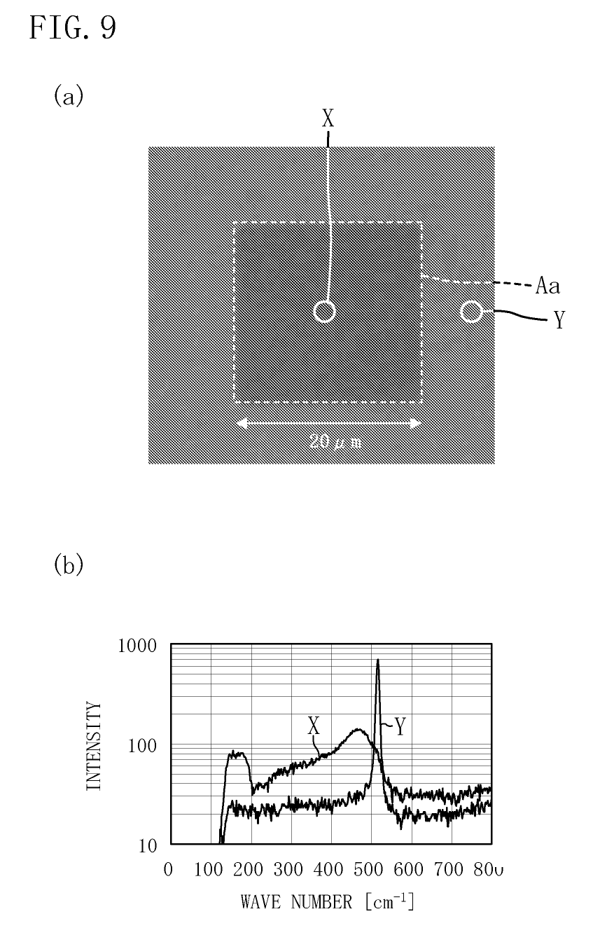

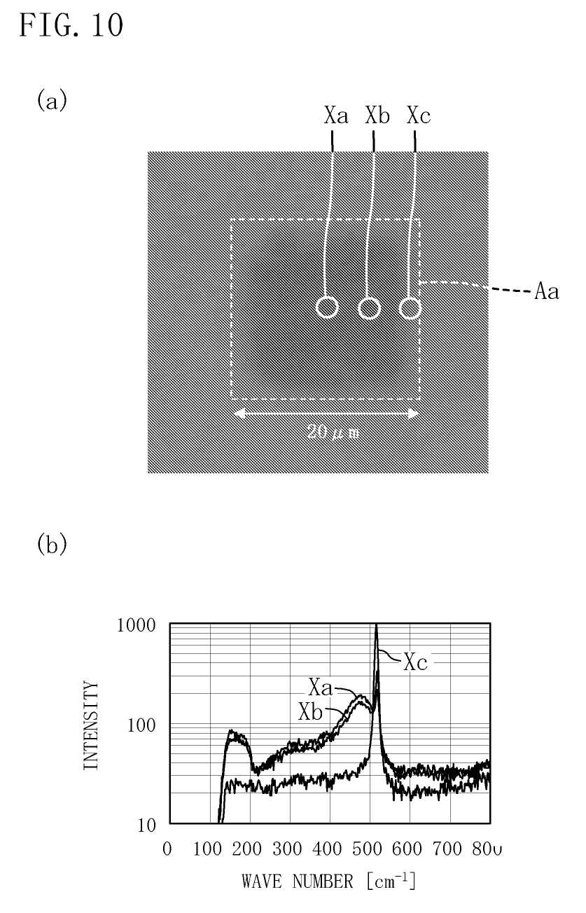

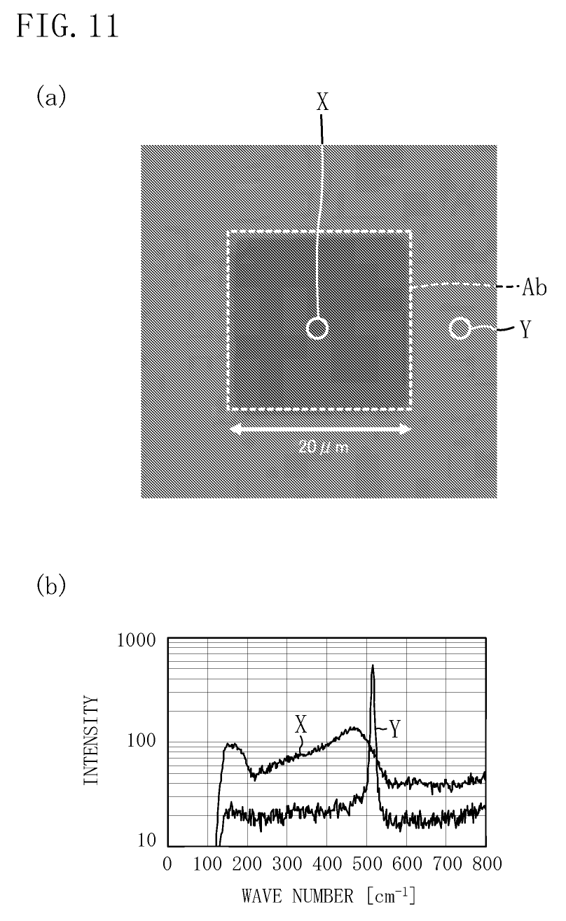

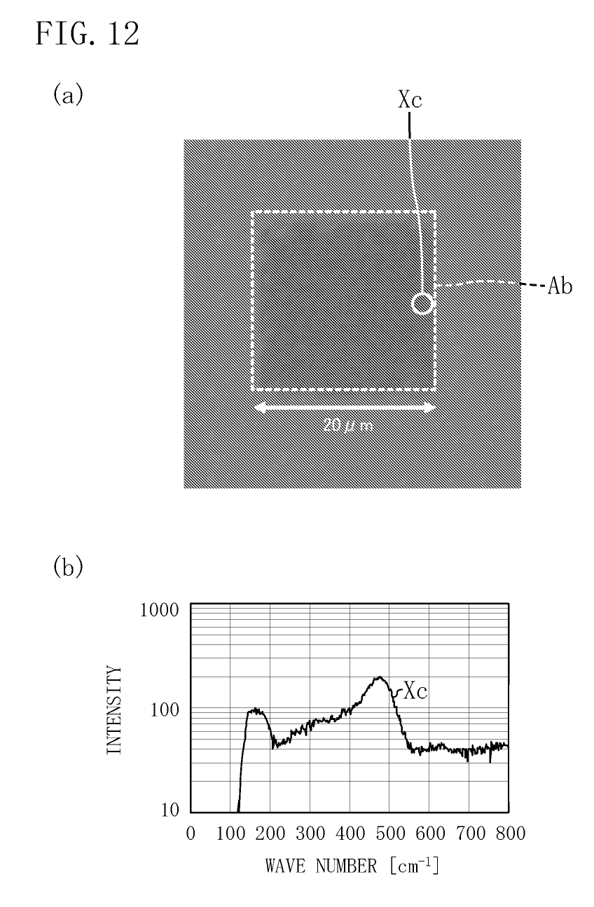

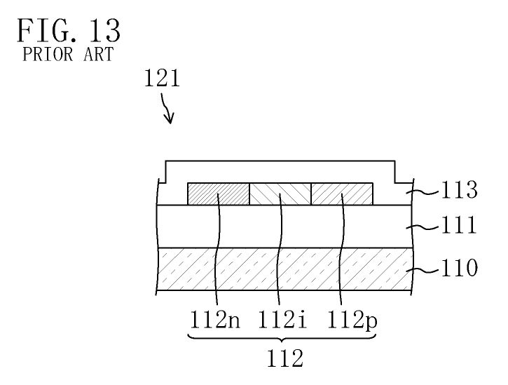

As described above, according to the TFD 21 of this embodiment and the fabrication method for the same, the doping of impurity ions is performed such that in the n-type semiconductor region formation process step, the concentration of the impurity ions in a multilayer of the polysilicon layer 12a and the gate insulating film 13 along the thickness of the multilayer reaches a peak concentration in the insulating film 13 or in a portion of the polysilicon layer 12a located between the midpoint of the thickness of the polysilicon layer 12a and the insulating film 13. Thus, the concentration of the impurity ions in the n-type semiconductor region 12an of the polysilicon layer 12a is lowest in the surface of the polysilicon layer 12a located near the glass substrate 10, thereby reducing the destruction of the crystallinity of a part of the polysilicon layer 12a located near the glass substrate 10. When the finding (see FIGS. 9 and 10) that as described above, while the crystallinity of a portion, which is in contact with a non-implanted region, of a region into which impurity ions are implanted is quickly recovered, the crystallinity of a central portion thereof which is apart from the non-implanted region is slowly recovered, and thus, when the crystallinity of a region from which recovery of the crystallinity starts is high, this accelerates the recovery of the crystallinity is represented to correspond to the recovery of the crystallinity along the thickness, the recovery of the crystallinity starts from a part of the polysilicon layer 12a located near the glass substrate 10 in the heating process step, thereby accelerating the recovery of the crystallinity. The reason for this is that the destruction of the crystallinity of a part, which is located near the glass substrate 10, of the n-type semiconductor region 12an of the polysilicon layer 12a is reduced. As such, the crystallinity of the n-type semiconductor region 12an of the polysilicon layer 12a is increased as much as possible, thereby increasing the crystallinities of junctions of the polysilicon layer 12a as much as possible. Therefore, the crystallinities of the junctions are increased as much as possible, thereby improving the diode characteristics.

In this embodiment, a method in which the acceleration voltage in the doping of phosphorus ions is set low, thereby forming a part of the polysilicon layer 12a which is located near the glass substrate 10 and of which the destruction of the crystallinity is reduced was described as an example. However, in the present invention, a part of a polysilicon layer which is located near a glass substrate and of which the destruction of the crystallinity is reduced may be formed by increasing the thickness of the polysilicon layer, e.g., from 50 nm to 60 nm, or by allowing the thickness of a portion of a gate insulating film overlapping a TFD to be 20 nm greater than the thickness of, e.g., a portion thereof overlapping a TFT.

In this embodiment, a configuration in which the TFT 22 is provided, as a switching device, in each of the pixel regions R, G, and B was described as an example. However, in the present invention, a TFT may be utilized for a charging circuit for a capacitor 23 of each of sensor regions S, a read driver, etc.

In this embodiment, the configuration in which the destruction of the crystallinity of a part of the n-type semiconductor region 12an located near the glass substrate 10 is reduced was described as an example. However, the present invention may be configured such that the destruction of the crystallinity of a part of a p-type semiconductor region located near a glass substrate is reduced, or such that the destruction of the crystallinities of parts of both n-type and p-type semiconductor regions located near a glass substrate is reduced.

In this embodiment, the TFD 21 formed on the glass substrate 10 was described as an example. However, the present invention can be practiced also with a TFD formed on any other substrate, such as a plastic substrate or a stainless substrate.

### INDUSTRIAL APPLICABILITY

As described above, the present invention can improve the diode characteristics of the TFD, and thus, is useful for a display, a touch panel, an image sensor, etc., including a TFD.

### DESCRIPTION OF REFERENCE CHARACTERS

10 Glass Substrate
12a, 12b Polysilicon Layer
12ai I-type Semiconductor Region
12an N-type Semiconductor Region
12ap P-type Semiconductor Region
13 Gate Insulating Film
TFD
TFT

1: A thin film diode, comprising:
a glass substrate;
a polysilicon layer formed on the glass substrate, and including a p-type semiconductor region and an n-type semiconductor region which are both formed in a same plane and doped with impurity ions; and
an insulating film provided to cover the polysilicon layer,
wherein in at least one of the p-type semiconductor region or the n-type semiconductor region, a concentration of the impurity ions in a multilayer of the polysilicon layer and the insulating film along a thickness of the multilayer reaches a peak concentration in the insulating film or in a portion of the polysilicon layer located between a midpoint of a thickness of the polysilicon layer and the insulating film.

2: The thin film diode of claim 1, wherein
in at least one of the p-type semiconductor region or the n-type semiconductor region, the concentration of the impurity ions in a surface of the polysilicon layer located near the glass substrate is less than or equal to 1/10 of a peak of the concentration of the impurity ions in the multilayer of the polysilicon layer and the insulating film along the thickness.

3: The thin film diode of claim 1, wherein
an i-type semiconductor region which is not doped with impurity ions is provided between the p-type semiconductor region and the n-type semiconductor region.

4: The thin film diode of claim 1, further comprising:
a further polysilicon film formed in a layer in which the polysilicon layer is formed,
wherein the further polysilicon layer forms a portion of a thin film transistor.

5: A method for fabricating a thin film diode, the method comprising:
a polysilicon layer formation step of forming a polysilicon layer on a glass substrate;
an insulating film formation step of forming an insulating film to cover the polysilicon layer;
a p-type semiconductor region formation step of doping the polysilicon layer with impurity ions via the insulating film, thereby forming a p-type semiconductor region;
an n-type semiconductor region formation step of doping the polysilicon layer with impurity ions via the insulating film, thereby forming an n-type semiconductor region;
a heating step of heating the glass substrate over which the p-type semiconductor region and the n-type semiconductor region are formed, thereby recovering a crystallinity of the polysilicon layer and activating the impurity ions with which the polysilicon layer is doped,
wherein in at least one of the p-type semiconductor region formation step or the n-type semiconductor region formation step, the polysilicon layer is doped with the impurity ions such that a concentration of the impurity ions in a multilayer of the polysilicon layer and the insulating film along a thickness of the multilayer reaches a peak concentration in the insulating film or in a portion of the polysilicon layer located between a midpoint of a thickness of the polysilicon layer and the insulating film.

6: The method of claim 5, wherein
in at least one of the p-type semiconductor region formation step or the n-type semiconductor region formation step, an acceleration voltage in the doping of the impurity ions is set low such that the concentration of the impurity ions in the multilayer of the polysilicon layer and the insulating film along the thickness of the multilayer reaches a peak concentration in the insulating film or in the portion of the polysilicon layer located between the midpoint of the thickness of the polysilicon layer and the insulating film.

7: The method of claim 5, wherein
in the insulating film formation step, the insulating film is formed thick enough to allow the concentration of the impurity ions in a multilayer of the insulating film and at least one of a region of the polysilicon layer which will form the p-type semiconductor region or a region of the polysilicon layer which will form the n-type semiconductor region along the thickness of the multilayer to reach a peak concentration in the insulating film or in the portion of the polysilicon layer located between the midpoint of the thickness of the polysilicon layer and the insulating film.

8: The method of claim 5, wherein
in the polysilicon layer formation step, the polysilicon layer is formed thick enough to allow the concentration of the impurity ions in a multilayer of the insulating film and at least one of a region of the polysilicon layer which will form the p-type semiconductor region or a region of the polysilicon layer which will form the n-type semiconductor region along the thickness of the multilayer to reach a peak concentration in the insulating film or in the portion of the polysilicon layer located between the midpoint of the thickness of the polysilicon layer and the insulating film.

9: The thin film diode of claim 2, wherein
an i-type semiconductor region which is not doped with impurity ions is provided between the p-type semiconductor region and the n-type semiconductor region.

10: The thin film diode of claim 2, further comprising:
a further polysilicon film formed in a layer in which the polysilicon layer is formed,
wherein the further polysilicon layer forms a portion of a thin film transistor.

11: The thin film diode of claim 3, further comprising:
a further polysilicon film formed in a layer in which the polysilicon layer is formed,
wherein the further polysilicon layer forms a portion of a thin film transistor.

12: The thin film diode of claim 9, further comprising:
a further polysilicon film formed in a layer in which the polysilicon layer is formed,
wherein the further polysilicon layer forms a portion of a thin film transistor.
